(19) United States
(12) Patent Application Publication
(10) Pub. No.: US 2026/0214946 A1
(43) Pub. Date: Jul. 23, 2026

(54) THIN FILM TRANSISTOR AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP); Emi KAWASHIMA, Tokyo (JP); Yuki TSURUMA, Tokyo (JP); Daichi SASAKI, Tokyo (JP)

(73) Assignees: Japan Display Inc., Tokyo (JP); IDEMITSU KOSAN CO., LTD., Tokyo (JP)

(21) Appl. No.: 19/577,405

(22) Filed: Mar. 25, 2026

Related U.S. Application Data
(63) Continuation of application No. PCT/JP2024/031586, filed on Sep. 3, 2024.

(30) Foreign Application Priority Data
Sep. 26, 2023 (JP) 2023-163570

(51) Int. Cl. H10D 30/67; H10D 30/01; H10D 62/40

(52) U.S. Cl. CPC H10D 30/6755; H10D 30/0314; H10D 30/6731; H10D 62/405

(57) ABSTRACT

A thin film transistor includes an oxide semiconductor layer having a polycrystalline structure, a metal oxide layer in contact with the oxide semiconductor layer, a gate electrode provided so as to overlap the oxide semiconductor layer, a gate insulating layer provided between the oxide semiconductor layer and the gate electrode. The oxide semiconductor layer includes a plurality of crystal grains, each of which has at least one of a crystal orientation <101>, a crystal orientation <111>, and a crystal orientation <001> that are measured by an electron backscatter diffraction method. The oxide semiconductor layer includes a first region in which the crystal orientation <101> is oriented within 15 degrees with respect to a normal direction of a surface of the semiconductor layer. An occupancy ratio of the first region is greater than or equal to 20%.

### CROSS-REFERENCE TO RELATED APPLICATIONS

This application is a Continuation of International Patent Application No. PCT/JP2024/031586, filed on Sep. 3, 2024, which claims the benefit of priority to Japanese Patent Application No. 2023-163570, filed on Sep. 26, 2023, the entire contents of each are incorporated herein by reference.

### FIELD

An embodiment of the present invention relates to a thin film transistor including an oxide semiconductor film having a polycrystalline structure (Poly-OS film). Further, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication Nos. 2021-141338, 2014-099601, 2021-153196, 2018-006730, 2016-184771, and 2021-108405). The thin film transistor including an oxide semiconductor film can be manufactured with a simple structure and low-temperature process, similar to a thin film transistor including an amorphous silicon film. Further, the thin film transistor including an oxide semiconductor film is known to have a higher field-effect mobility than the thin film transistor including an amorphous silicon film.

### SUMMARY

A thin film transistor according to an embodiment of the present invention includes an oxide semiconductor layer having a polycrystalline structure, a metal oxide layer in contact with the oxide semiconductor layer, a gate electrode provided so as to overlap the oxide semiconductor layer, and a gate insulating layer provided between the oxide semiconductor layer and the gate electrode. The oxide semiconductor layer includes a plurality of crystal grains, each of which has at least one of a crystal orientation <101>, a crystal orientation <111>, and a crystal orientation <001> that are measured by an electron backscatter diffraction method. The oxide semiconductor layer includes a first region in which the crystal orientation <101> is oriented within 15 degrees with respect to a normal direction of a surface of the semiconductor layer. An occupancy ratio of the first region is greater than or equal to 20%.

A thin film transistor according to an embodiment of the present invention includes an oxide semiconductor layer having a polycrystalline structure, a metal oxide layer in contact with the oxide semiconductor layer, a gate electrode provided so as to overlap the oxide semiconductor layer, and a gate insulating layer provided between the oxide semiconductor layer and the gate electrode. The oxide semiconductor layer includes a plurality of crystal grains, each of which has at least one of a crystal orientation <101>, a crystal orientation <111>, and a crystal orientation <001> that are measured by an electron backscatter diffraction method. In the oxide semiconductor layer, a region in which the crystal orientation <101> is oriented within 15 degrees with respect to a normal direction of a surface of the semiconductor layer is defined as a first region, a region in which the crystal orientation <111> is oriented within 15 degrees with respect to the normal direction of the surface of the semiconductor layer is defined as a second region, and a region in which the crystal orientation <001> is oriented within 15 degrees with respect to the normal direction of the surface of the semiconductor layer is defined as a third region. An occupancy ratio of the third region is less than an occupancy ratio of the first region and an occupancy ratio of the second region.

An electronic device according to an embodiment of the present invention includes the thin film transistor.

### BRIEF DESCRIPTION OF DRAWINGS

FIG. 1 is a schematic diagram illustrating a method for measuring an oxide semiconductor film by an EBSD method.

FIG. 2 is a schematic diagram illustrating a coordinate system used in an EBSD method.

FIG. 3 is a schematic cross-sectional view showing a configuration of a thin film transistor according to an embodiment of the present invention.

FIG. 4 is a schematic plan view showing a configuration of a thin film transistor according to an embodiment of the present invention.

FIG. 5 is a flowchart showing a method for manufacturing a thin film transistor according to an embodiment of the present invention.

FIG. 6 is a schematic cross-sectional view showing a method for manufacturing a thin film transistor according to an embodiment of the present invention.

FIG. 7 is a schematic cross-sectional view showing a method for manufacturing a thin film transistor according to an embodiment of the present invention.

FIG. 8 is a schematic cross-sectional view showing a method for manufacturing a thin film transistor according to an embodiment of the present invention.

FIG. 9 is a schematic cross-sectional view showing a method for manufacturing a thin film transistor according to an embodiment of the present invention.

FIG. 10 is a schematic cross-sectional view showing a method for manufacturing a thin film transistor according to an embodiment of the present invention.

FIG. 11 is a schematic cross-sectional view showing a method for manufacturing a thin film transistor according to an embodiment of the present invention.

FIG. 12 is a schematic cross-sectional view showing a method for manufacturing a thin film transistor according to an embodiment of the present invention.

FIG. 13 is a schematic cross-sectional view showing a method for manufacturing a thin film transistor according to an embodiment of the present invention.

FIG. 14 is a schematic cross-sectional view showing a method for manufacturing a thin film transistor according to an embodiment of the present invention.

FIG. 15 is a schematic diagram showing an electronic device according to an embodiment of the present invention.

FIG. 16 is an IPF map in an ND of Example Sample 1-1 obtained by crystal orientation analysis using an EBSD method.

FIG. 17 is an IPF map in an ND of Example Sample 1-1 obtained by crystal orientation analysis using an EBSD method.

FIG. 18 is an IPF map in an ND of Example Sample 1-2 obtained by crystal orientation analysis using an EBSD method.

FIG. 19 is an IPF map in an ND of Example Sample 1-2 obtained by crystal orientation analysis using an EBSD method.

FIG. 20 is an IPF map in an ND of Example Sample 1-3 obtained by crystal orientation analysis using an EBSD method.

FIG. 21 is an IPF map in an ND of Example Sample 1-3 obtained by crystal orientation analysis using an EBSD method.

FIG. 22 is an IPF map in an ND of Example Sample 1-4 obtained by crystal orientation analysis using an EBSD method.

FIG. 23 is an IPF map in an ND of Example Sample 1-4 obtained by crystal orientation analysis using an EBSD method.

FIG. 24A is a graph showing a distribution diagram of all adjacent point orientation changes of Example Sample 1-1.

FIG. 24B is a graph showing a distribution diagram of KAM values of Example Sample 1-1.

FIG. 24C is a graph showing a distribution diagram of grain boundary orientation changes of Example Sample 1-1.

FIG. 25A is a graph showing a distribution diagram of all adjacent point orientation changes of Example Sample 1-2.

FIG. 25B is a graph showing a distribution diagram of KAM values of Example Sample 1-2.

FIG. 25C is a graph showing a distribution diagram of grain boundary orientation changes of Example Sample 1-2.

FIG. 26A is a graph showing a distribution diagram of all adjacent point orientation changes of Example Sample 1-3.

FIG. 26B is a graph showing a distribution diagram of KAM values of Example Sample 1-3.

FIG. 26C is a graph showing a distribution diagram of grain boundary orientation changes of Example Sample 1-3.

FIG. 27A is a graph showing a distribution diagram of all adjacent point orientation changes of Example Sample 1-4.

FIG. 27B is a graph showing a distribution diagram of KAM values of Example Sample 1-4.

FIG. 27C is a graph showing a distribution diagram of grain boundary orientation changes of Example Sample 1-4.

FIG. 28 is a graph showing a correlation between a grain boundary parameter PGB and a field effect mobility in Example Samples 1-1 to 1-4.

### DESCRIPTION OF EMBODIMENTS

The field effect mobility of a thin film transistor including a conventional oxide semiconductor film is not so high even when a crystalline oxide semiconductor film is used in the thin film transistor. Therefore, it has been desired to improve the crystal structure of the oxide semiconductor film used in the thin film transistor and thereby improve the field effect mobility of the thin film transistor.

In view of the above problems, an embodiment of the present invention can provide a thin film transistor including an oxide semiconductor film having a novel crystal structure. Further, an embodiment of the present invention can provide an electronic device including the thin film transistor.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a thin film transistor and a pixel electrode do not overlap in a plan view when expressed as “a pixel electrode over a thin film transistor.” On the other hand, the expression “a pixel electrode vertically over a thin film transistor” means a positional relationship in which the thin film transistor and the pixel electrode overlap in a plan view. In addition, a plan view refers to viewing from a direction perpendicular to a surface of the substrate.

In the present specification and the like, the terms “film” and “layer” can be optionally interchanged with one another.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “a includes A, B, or C,” “a includes any of A, B, or C,” or “a includes one selected from a group consisting of A, B and C,” and the like does not exclude the case where a includes a plurality of combinations of A to C unless otherwise specified. Further, these expressions do not exclude the case where a includes other components.

In addition, the following embodiments can be combined with each other as long as there is no technical contradiction.

### First Embodiment

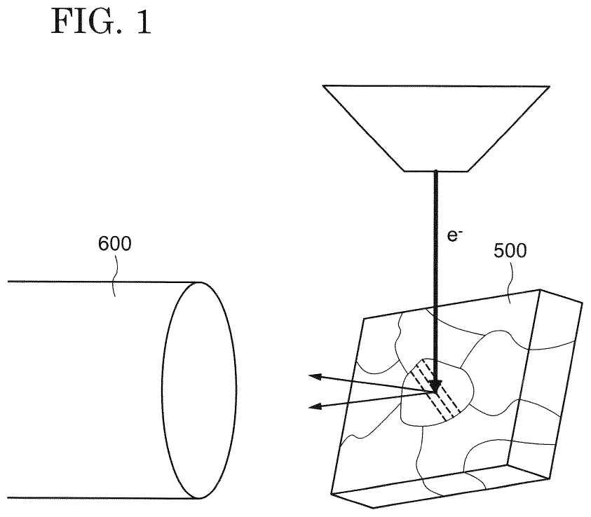

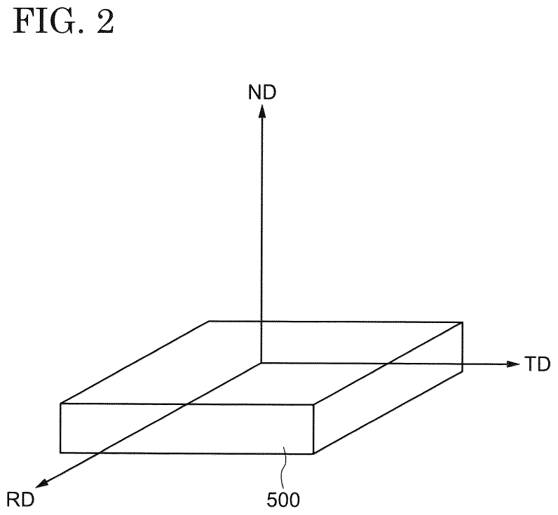

An oxide semiconductor film according to an embodiment of the present invention is described with reference to FIGS. 1 and 2.

### [1. Composition of Oxide Semiconductor Film]

The oxide semiconductor film according to the present embodiment contains indium (In) and at least one or more metal elements (M) other than indium. It is preferable that the composition ratio of the oxide semiconductor film has an atomic ratio of indium and at least one or more metal elements which satisfies Formula (1). In other words, it is preferable that the ratio of indium to all metal elements in the oxide semiconductor film is greater than or equal to 50%. When the ratio of indium in the oxide semiconductor film increases, the oxide semiconductor film having crystallinity can be formed. Further, it is preferable that a crystal structure of the oxide semiconductor film has a bixbyite structure. When the ratio of indium in the oxide semiconductor film increases, the oxide semiconductor film having a bixbyite structure can be formed.

$$0.01 < \frac{[ M ]}{[ ln ] + [ M ]} < 0.5 \qquad ( 1 )$$

In addition, the metal element other than indium is not limited to one kind of metal element. A plurality of kinds of metal elements may be contained in the oxide semiconductor film as the metal element other than indium.

Although the details of a method for manufacturing the oxide semiconductor film are described later together with a method for manufacturing a thin film transistor, the oxide semiconductor film can be formed by a sputtering method. The composition of the oxide semiconductor film formed by the sputtering method depends on the composition of the sputtering target. When the sputtering target has the above-described composition, the oxide semiconductor film without composition deviation of the metal elements can be formed by the sputtering method. Therefore, the composition of the metal elements (indium and other metal elements) in the oxide semiconductor film may be equivalent to the composition of the metal elements in the sputtering target. For example, the composition of the metal elements in the oxide semiconductor film can be specified based on the composition of the metal elements in the sputtering target. In addition, oxygen contained in the oxide semiconductor film is not limited thereto because it changes depending on the process conditions of the sputtering method.

Further, the composition of the metal elements in the oxide semiconductor film can be specified by X-ray fluorescence analysis, electron probe micro analyzer (EPMA) analysis, or the like. Since the oxide semiconductor film has crystallinity, the composition of the oxide semiconductor film may be specified by X-ray diffraction (XRD). Specifically, the composition of the metal elements in the oxide semiconductor film can be specified based on the crystal structure and lattice constant of the oxide semiconductor film obtained by XRD.

### [2. Crystal Structure of Oxide Semiconductor Film]

The oxide semiconductor film according to the present embodiment has crystallinity. Although the details of the configuration of the oxide semiconductor film are described later, the oxide semiconductor film having a novel polycrystalline structure different from a conventional oxide semiconductor film can be formed using a polycrystalline oxide semiconductor (Poly-OS) technique. Therefore, hereinafter, the oxide semiconductor film having a polycrystalline structure according to the present embodiment may be referred to as a Poly-OS film in order to distinguish it from the conventional oxide semiconductor film having a polycrystalline structure.

Each crystal grain in the Poly-OS film may be composed of a plurality of crystallites. Although the crystallite diameter is not particularly limited to a certain value, the crystallite diameter is preferably greater than or equal to 1 nm, more preferably greater than or equal to 10 nm, and further preferably greater than or equal to 15 nm. The crystallite diameter can be measured by an electron beam diffraction method, an XRD method, or the like.

Although the crystal structure of the Poly-OS film is not limited to a certain structure, it is preferable that the Poly-OS film has a bixbyite structure. The crystal structure of the Poly-OS film can be specified by an XRD method or an electron beam diffraction method.

In addition, a plurality of crystal grains may have one type of crystal structure, or may have a plurality of types of crystal structures in the Poly-OS film. When the Poly-OS film has the plurality of types of crystal structures, it is preferable that one of the plurality of types of crystal structures is a bixbyite structure.

The crystal structure of the Poly-OS film is different from that of the conventional oxide semiconductor film having a polycrystalline structure. Specifically, the present inventors found that the crystal grains included in the Poly-OS film have characteristics different from those of the crystal grains included in the conventional oxide semiconductor film. Such characteristics of the Poly-OS film can be measured by an electron backscatter diffraction (EBSD) method. Hereinafter, measurement of the oxide semiconductor film by an EBSD method is described.

### [2-1. EBSD Method]

An EBSD method is an analysis method in which an object to be measured is irradiated with an electron beam, and electron backscatter diffraction generated on each crystal plane of the crystal structure of the object to be measured is analyzed to measure the crystal structure in a measurement region of the object to be measured. The EBSD method can obtain information such as crystal orientations or crystal grains of the oxide semiconductor film in the measurement region by analyzing data obtained from an EBSD detector attached to a scanning electron microscope (SEM) or a transmission electron microscope (TEM).

FIG. 1 is a schematic diagram illustrating a method for measuring an oxide semiconductor film by the EBSD method. Further, FIG. 2 is a schematic diagram illustrating a coordinate system used in the EBSD method.

As shown in FIG. 1, when an electron beam is irradiated onto a surface of an oxide semiconductor film 500 tilted at a predetermined angle (e.g., 70 degrees), the electron beam is diffracted by each crystal plane of the crystalline structure of the oxide semiconductor film 500, and diffracted electron beams having an EBSD pattern corresponding to the crystal orientation are emitted. This EBSD pattern is detected by an EBSD detector 600 (e.g., a CCD sensor or a CMOS sensor), and crystal orientation analysis, such as indexing of the crystal orientations, is performed on the EBSD pattern to determine the crystal orientations. Further, when the electron beam is scanned and the EBSD pattern is mapped, information such as the crystal orientations and crystal grains on the surface of the oxide semiconductor film 500 can be obtained. In crystal orientation analysis using the EBSD method, a coordinate system consisting of a rolling direction (RD), a transverse direction (TD), and a normal direction (ND) is used, as shown in FIG. 2. When the surface of the oxide semiconductor film 500 is irradiated with the electron beam, the RD and the TD correspond to the in-plane directions of the oxide semiconductor film 500, and the ND corresponds to the normal direction to the surface of the oxide semiconductor film 500.

In addition, when the oxide semiconductor film 500 is provided on a flat substrate, the surface of the oxide semiconductor film 500 is approximately parallel to the surface of the substrate. In this case, the ND may be described as corresponding to the normal direction to the surface of the substrate.

### [2-2. IPF Map]

An IPF (Inverse Pole Figure) map is an image in which the crystal orientations in a specific direction (ND, RD, or TD) of the object being measured are defined according to a predetermined index. In general, the crystal orientations are color-coded according to a color key. Crystal orientation information at each measurement point can be obtained in a measurement using the EBSD method. Therefore, the IPF map can be created based on the crystal orientation information obtained at each measurement point. Further, the area of each defined region can be obtained in an IPF map, and the ratio to the area of the entire measurement region (hereinafter, referred to as “occupancy ratio”) can be calculated and quantitatively compared.

The IPF map may be an image obtained by extracting data from measurement points where the crystal orientation difference with respect to the normal direction of the substrate surface (or the surface of the oxide semiconductor film) is within a predetermined angle range. In other words, the IPF map may be an image obtained by extracting regions where a specific crystal orientation is oriented within a predetermined angle range with respect to the normal direction of the substrate surface. For example, the predetermined angle range is greater than or equal to 0 degrees and less than or equal to 15 degrees. Since such an IPF map excludes measurement points with crystal orientations that are significantly tilted from the normal direction of the substrate surface, crystal orientations that tend to be oriented with respect to the normal direction of the substrate surface can be revealed. Therefore, when the occupancy ratios of regions containing the plurality of crystal orientations are compared, it is possible to more clearly specify crystal orientations that tend to be oriented with respect to the normal direction of the substrate surface.

When the oxide semiconductor film according to the present embodiment has a bixbyite structure, the occupancy ratio of the region where the crystal orientation <101> is oriented within 15 degrees with respect to the normal direction (ND) of the substrate surface (hereinafter, referred to as the “crystal orientation <101> region”) is greater than or equal to 20%, and preferably greater than or equal to 21%. The occupancy ratio of the region where the crystal orientation <111> is oriented within 15 degrees with respect to the ND (hereinafter, referred to as the “crystal orientation <111> region”) is greater than or equal to 15%, preferably greater than or equal to 18%. Further, the occupancy ratio of the region where the crystal orientation <001> is oriented within 15 degrees with respect to the ND (hereinafter, referred to as the “crystal orientation <001> region”) is less than 10%, preferably less than or equal to 8%. In other words, the occupancy ratio of the crystal orientation <001> region is smaller than the occupancy ratio of the crystal orientation <101> region and the occupancy ratio of the crystal orientation <111> region. The occupancy ratio of the crystal orientation <101> region is at least twice as high as the occupancy ratio of the crystal orientation <001> region. Further, the occupancy ratio of the region of the crystal orientation <111> is at least 1.5 times as high as the occupancy ratio of the crystal orientation <001> region. In addition, the occupancy ratio of the crystal orientation <101> region is preferably larger than the occupancy ratio of the crystal orientation <111> region. The crystal orientations <101> and <111> have a smaller effective mass of electrons in the conduction bands and a higher electron mobility than the crystal orientation <001>. Therefore, when the oxide semiconductor film in which the occupancy ratio of the crystal orientation <101> region and the occupancy ratio of the crystal orientation <111> region are larger than the occupancy ratio of the crystal orientation <001> region is used as a channel, the field effect mobility of the thin film transistor can be improved.

Here, the crystal orientation <001> represents and its equivalents and [010]. The crystal orientation <101> represents and its equivalents and [011]. The crystal orientation <111> represents [111]. Further, in each orientation, “1” may be “−1” and is considered to be an axis equivalent to each orientation.

In addition, crystal orientations include <hk0> (h≠k, h and k are natural numbers), <hhl> (h≠l, h and l are natural numbers), and <hkl> (h≠k≠l, h, k, and l are natural numbers) other than <001>, <101>, and <111>.

### [2-3. Crystal Grain]

A crystal grain is a crystalline region surrounded by a grain boundary. Since the EBSD method obtains information on the crystal orientation, the grain boundary can be defined based on the crystal orientations. In general, when the crystal orientation difference between two adjacent measurement points exceeds 5 degrees, it is defined that a grain boundary exists between them. Therefore, the above definition is also applied to the oxide semiconductor film.

### [2-4. Crystal Grain Size]

A crystal grain size is a value representing the size of a crystal grain. Since the area S of the crystal grain can be calculated in the EBSD method, the diameter of a circle corresponding to the area S is defined as the crystal grain size d.

### [2-5. Average Crystal Grain Size]

An average crystal grain size is an average value of crystal grain sizes of a plurality of crystal grains. Since the Poly-OS film includes a plurality of crystal grains, the Poly-OS film can be evaluated using the average crystal grain size. The average crystal grain size d_{AVE} is calculated by Formula (2). Here, Aⱼ is the area ratio of the j-th crystal grain (the ratio of the area of the crystal grain to the area of the entire EBSD measurement region (the measurement region)), dⱼ is the crystal grain size of the j-th crystal grain, and N is the number of crystal grains. As shown in Formula (2), the average crystal grain size d_{AVE} is the average area in the measurement region weighted by the area of the crystal grains. When the average crystal grain size d_{AVE} of an oxide semiconductor film is large, it can be said that many crystal grains with a large crystal grain size are present in the oxide semiconductor film.

$${d}_{AVE} = {\sum }_{j = 1}^{N} {A}_{j} * {d}_{j} \qquad ( 2 )$$

For example, the average crystal grain size of the plurality of crystal grains included in the Poly-OS film is greater than or equal to 0.1 μm, preferably greater than or equal to 0.3 μm, and more preferably greater than or equal to 0.5 μm.

### [2-6. KAM Value]

A KAM (Kernel Average Misorientation) value is an average value of crystal orientation differences between one measurement point in a crystal grain and all measurement points adjacent to the one measurement point in the crystal grain. The KAM value is a value calculated based on two adjacent measurement points in one crystal grain. Therefore, a crystal orientation difference between two adjacent measurement points with a grain boundary interposed therebetween is excluded from the calculation of the KAM value.

The KAM value is a value that represents the change in crystal orientation in one crystal grain. As described above, when a crystal orientation difference between one measurement point and another measurement point adjacent to that measurement point exceeds 5 degrees, it is considered to be a grain boundary. Therefore, the range of the KAM value calculated based on adjacent measurement points in one crystal grain is greater than or equal to 0 degrees and less than or equal to 5 degrees. A large KAM value means that the local change in crystal orientation in the crystal grain is large, and the crystal grain has a large strain.

The KAM value is calculated at each of the plurality of measurement points. Therefore, a distribution diagram of the KAM values in the crystal grains can be created. Further, the average KAM value can be calculated based on the distribution diagram of the KAM values. The average KAM value represents one of the properties of the crystal grains contained in the Poly-OS film. Since the Poly-OS film has a large change in crystal orientation and contains many crystal grains with a large strain, the average KAM value of the Poly-OS film is larger than that of the conventional oxide semiconductor film having a polycrystalline structure. The average KAM value of the Poly-OS film is greater than or equal to 1.0 degree, preferably greater than or equal to 2.0 degrees, and more preferably greater than or equal to 3.0 degrees. A large KAM value in the Poly-OS film means a large deviation in crystal orientation in the crystal grains, which results in a small crystal orientation difference at the crystal grain boundaries. This results in high lattice matching and few defects at the crystal grain boundaries, which suppresses grain boundary scattering and improves bulk mobility. Therefore, in a thin film transistor including the Poly-OS film as a channel, the grain boundary scattering is suppressed in the Poly-OS film and the field effect mobility of the thin film transistor is improved.

### [2-7. Grain Boundary Orientation Change]

A grain boundary orientation change is a crystal orientation difference between two adjacent measurement points across a grain boundary. That is, the grain boundary orientation change corresponds to the crystal orientation difference excluded in the calculation of the KAM value.

The grain boundary orientation change is a value that represents the change in the crystal orientation at the grain boundary. As described above, since the grain boundary has a crystal orientation difference greater than 5 degrees, the grain boundary orientation change is in the range greater than 5 degrees. When the grain boundary orientation change is large, the change in the crystal orientation of two adjacent crystal grains at the grain boundary is large, and the degree of coincidence of the crystal orientation of the two adjacent crystal grains at the grain boundary is low. In other words, when the grain boundary orientation change is large, it means that there is a grain boundary with low lattice matching and many defects. In contrast, when the grain boundary orientation change is small, it means that there is a grain boundary with high lattice matching and few defects. Here, the lattice matching is defined as the degree of coincidence of the lattice constant and the crystal orientation in two crystal grains.

An average value of the grain boundary orientation changes can be calculated based on the distribution diagram of the grain boundary orientation changes. The average value of the grain boundary orientation change is a value that represents one of the characteristics of the crystal grains included in the Poly-OS film. A small average value of the grain boundary orientation changes means that the Poly-OS film includes many grain boundaries with high lattice matching and few defects. In the Poly-OS film, the average value of the grain boundary orientation changes is less than or equal to 50 degrees, preferably less than or equal to 40 degrees, and more preferably less than or equal to 30 degrees.

As described above, the oxide semiconductor film according to an embodiment of the present invention, that is, the Poly-OS film, has the novel crystal structure. Since the Poly-OS film has high lattice matching and few defects at the grain boundaries, the grain boundary scattering is suppressed and the bulk mobility is improved. Therefore, in a thin film transistor including the Poly-OS film as a channel, the grain boundary scattering is suppressed in the Poly-OS film and the field effect mobility of the thin film transistor is improved.

### Second Embodiment

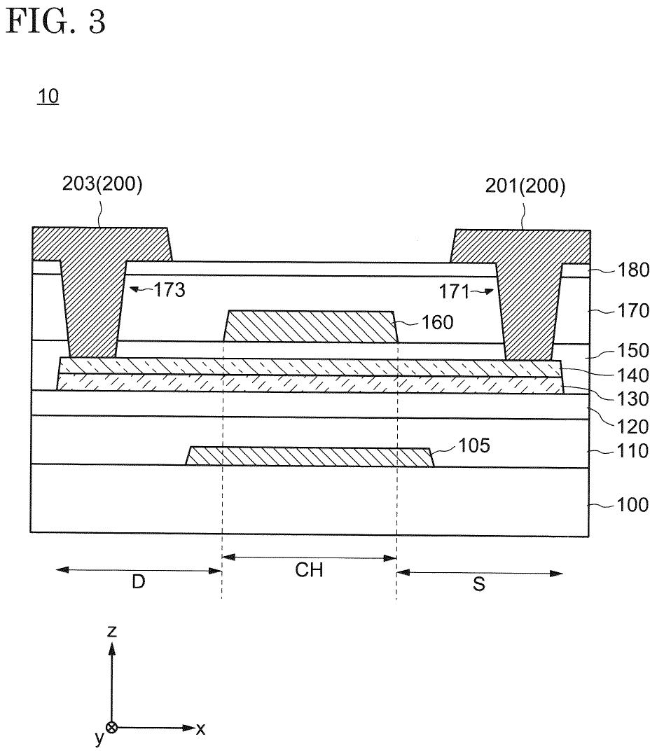

A thin film transistor 10 according to an embodiment of the present invention is described with reference to FIGS. 3 to 14. For example, the thin film transistor 10 may be used in a display device, an integrated circuit (IC) such as a microprocessor (MPU), or a memory circuit.

### [1. Configuration of Thin Film Transistor 10]

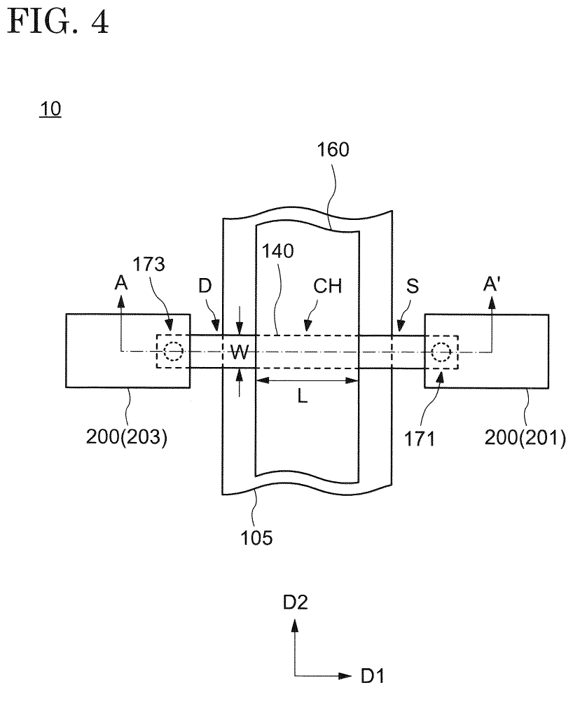

A configuration of a thin film transistor 10 according to an embodiment of the present invention is described with reference to FIGS. 3 and 4. FIG. 3 is a schematic cross-sectional view showing the configuration of the thin film transistor 10 according to an embodiment of the present invention. FIG. 4 is a schematic plan view showing the configuration of the thin film transistor 10 according to an embodiment of the present invention. Specifically, FIG. 3 is a cross-sectional view cut along the line A-A′ in FIG. 3.

As shown in FIG. 3, the thin film transistor 10 includes a substrate 100, a light shielding layer 105, a first insulating layer 110, a second insulating layer 120, a metal oxide layer 130, an oxide semiconductor layer 140, a gate insulating layer 150, a gate electrode 160, a third insulating layer 170, a fourth insulating layer 180, a source electrode 201, and a drain electrode 203. The light shielding layer 105 is provided on the substrate 100. The first insulating layer 110 is provided on the substrate 100 so as to cover an upper surface and an edge surface of the light shielding layer 105. The second insulating layer 120 is provided on the first insulating layer 110. The metal oxide layer 130 is provided on the second insulating layer 120. The oxide semiconductor layer 140 is provided on the metal oxide layer 130. The oxide semiconductor layer 140 is in contact with the metal oxide layer 130. The gate insulating layer 150 is provided on the second insulating layer 120 so as to cover an upper surface and an edge surface of the oxide semiconductor layer 140 and an edge surface of the metal oxide layer 130. The gate electrode 160 is provided on the gate insulating layer 150 so as to overlap the oxide semiconductor layer 140. The third insulating layer 170 is provided on the gate insulating layer 150 so as to cover an upper surface and an edge surface of the gate electrode 160. The fourth insulating layer 180 is provided on the third insulating layer 170. The gate insulating layer 150, the third insulating layer 170, and the fourth insulating layer 180 are provided with opening portions 171 and 173 through which a part of the upper surface of the oxide semiconductor layer 140 is exposed. The source electrode 201 is provided on the fourth insulating layer 180 and inside the opening portion 171, and is in contact with the oxide semiconductor layer 140. Similarly, the drain electrode 203 is provided on the fourth insulating layer 180 and inside the opening portion 173, and is in contact with the oxide semiconductor layer 140. In the following description, when the source electrode 201 and the drain electrode 203 are not particularly distinguished from each other, they may be collectively referred to as a source-drain electrode 200.

The oxide semiconductor layer 140 is divided into a source region S, a drain region D, and a channel region CH based on the gate electrode 160. That is, the oxide semiconductor layer includes the channel region CH which overlaps the gate electrode 160 and the source region S and the drain region D which do not overlap the gate electrode 160. In a thickness direction of the oxide semiconductor layer 140, an edge portion of the channel region CH is substantially aligned with an edge portion of the gate electrode 160. The channel region CH has properties of a semiconductor. Each of the source region S and the drain region D has properties of a conductor. Therefore, the electrical conductivities of the source region S and the drain region D are larger than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 4, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the thin film transistor 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105. Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The first insulating layer 110, the second insulating layer 120, the third insulating layer 170, and the fourth insulating layer 180 can prevent impurities from diffusing into the oxide semiconductor layer 140. Specifically, the first insulating layer 110 and the second insulating layer 120 can prevent diffusion of impurities contained in the substrate 100, and the third insulating layer 170 and the fourth insulating layer 180 can prevent diffusion of impurities (for example, water) entering from the outside. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for each of the first insulating layer 110, the second insulating layer 120, the third insulating layer 170, and the fourth insulating layer 180. Here, silicon oxynitride (SiOₓN_{y}) and aluminum oxynitride (AIOₓN_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, each of the first insulating layer 110, the second insulating layer 120, the third insulating layer 170, and the fourth insulating layer 180 may have a single layer structure or a laminated structure.

The second insulating layer 120 is preferably an insulating layer containing oxygen, such as silicon oxide (SiOₓ) and silicon oxynitride (SiOₓN_{y}). That is, when the second insulating layer 120 has a single layer structure, silicon oxide (SiOₓ) or silicon oxynitride (SiOₓN_{y}) is used for the second insulating layer 120, and when the second insulating layer 120 has a laminated structure, silicon oxide (SiOₓ) or silicon oxynitride (SiOₓN_{y}) is used for a layer included in the second insulating layer 120 and in contact with the oxide semiconductor layer 140.

Each of the first insulating layer 110, the second insulating layer 120, the third insulating layer 170, and the fourth insulating layer 180 may have a planarization function or a function of releasing oxygen by a heat treatment. For example, when the second insulating layer 120 has a function of releasing oxygen by a heat treatment, oxygen is released from the second insulating layer 120 by the heat treatment performed in the manufacturing process of the thin film transistor 10, and the released oxygen can be supplied to the oxide semiconductor layer 140.

For ease of explanation, silicon oxide (SiOₓ) and silicon oxynitride (SiOₓN_{y}) may be referred to simply as “silicon oxide” in the following description. Further, silicon nitride (SiNₓ) and silicon nitride oxide (SiNₓO_{y}) may be referred to simply as “silicon nitride” in the following description.

The metal oxide layer 130 includes an insulating metal oxide. Specifically, a metal oxide having a band gap greater than or equal to 4 eV is used for the metal oxide layer 130. Further, the metal oxide layer 130 may include, for example, a metal oxide containing one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid elements. In particular, it is preferable to use a metal oxide containing aluminum (e.g., aluminum oxide) for the metal oxide layer 130. A metal oxide containing aluminum has high barrier properties against gases such as oxygen and hydrogen.

Further, the metal oxide layer 130 can also function as a buffer layer for the oxide semiconductor layer 140. For example, when a heat treatment is performed on the oxide semiconductor layer 140 in contact with the metal oxide layer 130, the crystallinity of the oxide semiconductor layer 140 can be improved.

The gate electrode 160, the source electrode 201, and the drain electrode 203 are conductive. For example, copper (Cu), aluminum (AI), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, source electrode 201, and drain electrode 203 may have a single layer structure or a laminated structure.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AIOₓN_{y}), or the like is used for the gate insulating layer 150. The gate insulating layer 150 preferably has a composition close to the stoichiometric ratio. Further, the gate insulating layer 150 preferably has few defects. For example, an oxide in which few defects are observed when evaluated by electron spin resonance (ESR) may be used for the gate insulating layer 150.

The oxide semiconductor film having a polycrystalline structure (Poly-OS film) described in the First Embodiment can be used as the oxide semiconductor layer 140. For example, the thickness of the oxide semiconductor layer 140 is greater than or equal to 5 nm and less than or equal to 50 nm, preferably greater than or equal to 10 nm and less than or equal to 40 nm, and more preferably greater than or equal to 10 nm and less than or equal to 30 nm.

Although the configuration of the thin film transistor 10 is described above, the thin film transistor 10 described above is a so-called top-gate transistor. The thin film transistor 10 can be modified in various ways. For example, when the light shielding layer 105 has conductivity, the thin film transistor 10 may have a structure in which the light shielding layer 105 functions as a gate electrode, and the first insulating layer 110 and the second insulating layer 120 function as gate insulating layers. In this case, the thin film transistor 10 is a so-called dual-gate transistor. Further, when the light shielding layer 105 has conductivity, the light shielding layer 105 may be a floating electrode and may be connected to the source electrode 201. Furthermore, the thin film transistor 10 may be a so-called bottom-gate transistor in which the light shielding layer 105 functions as a main gate electrode.

### [2. Method for Manufacturing Thin Film Transistor 10]

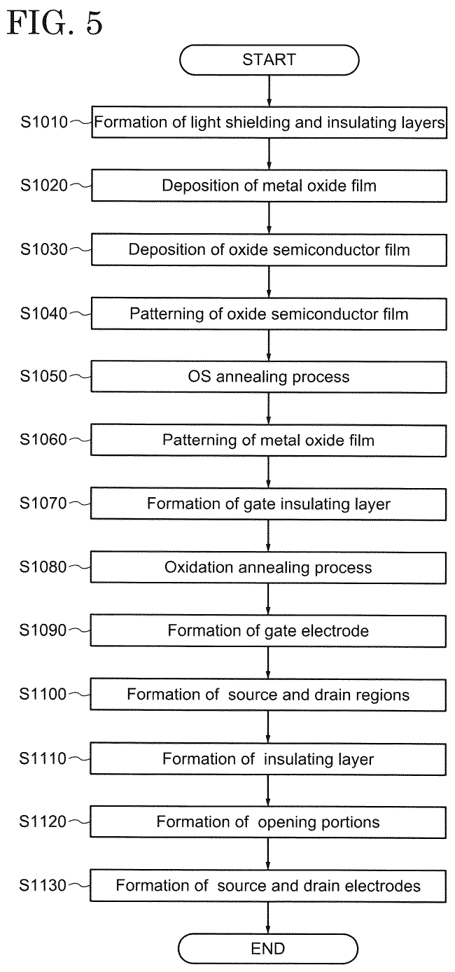

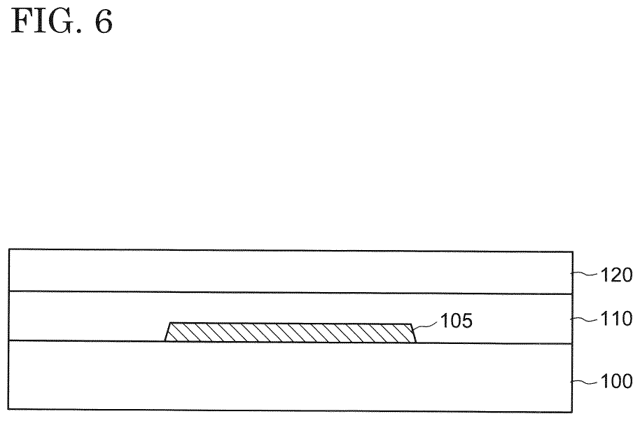

A method for manufacturing the thin film transistor 10 according to an embodiment of the present invention is described with reference to FIGS. 5 to 14. FIG. 5 is a flowchart showing the method for manufacturing the thin film transistor 10 according to an embodiment of the present invention. FIGS. 6 to 14 are schematic cross-sectional views showing the method of manufacturing the thin film transistor 10 according to an embodiment of the present invention.

As shown in FIG. 5, the method for manufacturing the thin film transistor 10 includes steps S1010 to S1130. In the following description, although steps S1010 to S1130 are described in order, the order of the steps may be interchanged in the method for manufacturing the thin film transistor 10. Further, the method for manufacturing the thin film transistor 10 may include additional steps.

In step S1010, the light shielding layer 105 having a predetermined pattern is formed on the substrate 100. The patterning of the light shielding layer 105 is performed using a photolithography method. The first insulating layer 110 and the second insulating layer 120 are formed on the light shielding layer 105 (see FIG. 6). The first insulating layer 110 and the second insulating layer 120 are deposited using a CVD method. For example, silicon nitride and silicon oxide are deposited as the first insulating layer 110 and the second insulating layer 120, respectively. When silicon nitride is used for the first insulating layer 110, the first insulating layer 110 can block impurities that diffuse from the substrate 100 into the oxide semiconductor layer 140. When silicon oxide is used for the second insulating layer 120, the second insulating layer 120 can release oxygen by a heat treatment.

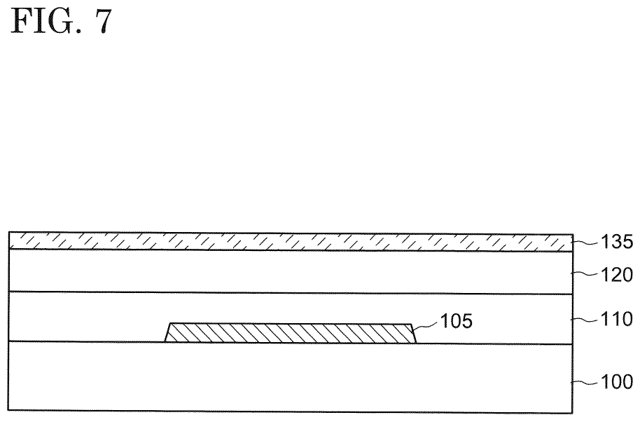

In step S1020, a metal oxide film 135 is deposited on the second insulating layer 120 (see FIG. 7). The metal oxide film 135 is deposited by a sputtering method. For example, the thickness of the metal oxide film 135 is greater than or equal to 2 nm and less than or equal to 51 nm, preferably greater than or equal to 2 nm and less than or equal to 31 nm, more preferably greater than or equal to 2 nm and less than or equal to 21 nm, and particularly preferably greater than or equal to 2 nm and less than or equal to 11 nm.

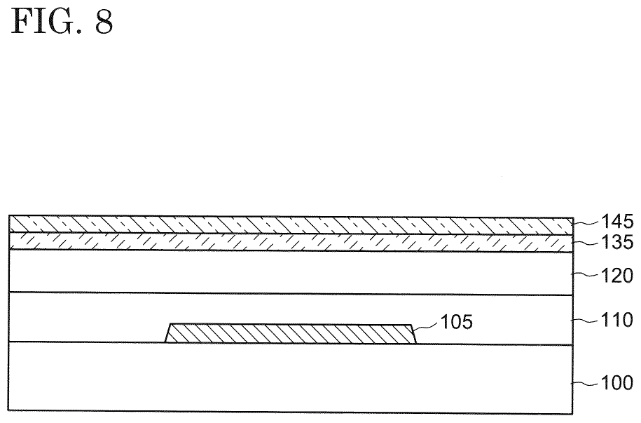

In step S1030, an oxide semiconductor film 145 is deposited on the metal oxide film 135 (see FIG. 8). The oxide semiconductor film 145 is deposited by a sputtering method. For example, the thickness of the oxide semiconductor film 145 is greater than or equal to 5 nm and less than or equal to 50 nm, preferably greater than or equal to 10 nm and less than or equal to 40 nm, and more preferably greater than or equal to 10 nm and less than or equal to 30 nm.

The oxide semiconductor film 145 in step S1030 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is formed by a sputtering method, the oxide semiconductor film 145 is deposited while controlling the temperature of the object to be deposited (the substrate 100 and the layers formed on the substrate 100) to less than or equal to 100° C., preferably less than or equal to 80° C., and more preferably less than or equal to 50° C. The oxygen partial pressure is greater than or equal to 2% and less than or equal to 20%, preferably greater than or equal to 3% and less than or equal to 15%, and more preferably greater than or equal to 3% and less than 10%.

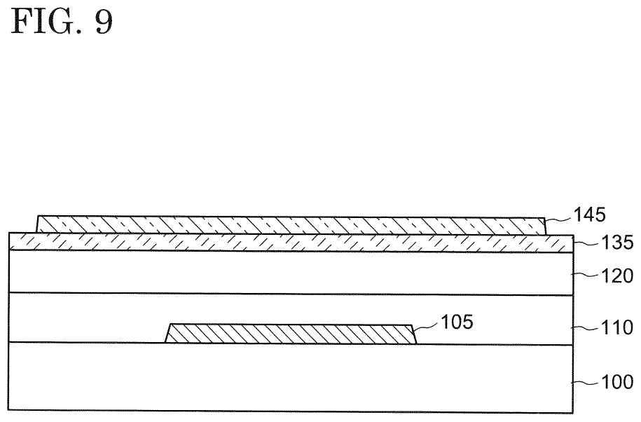

In step S1040, the oxide semiconductor film 145 is patterned (see FIG. 9). The patterning of the oxide semiconductor film 145 is performed using a photolithography method. Wet etching or dry etching may be used for the etching of the oxide semiconductor film 145. Wet etching can be performed using an acidic etchant. For example, oxalic acid, PAN, sulfuric acid, a hydrogen peroxide solution, hydrofluoric acid, or the like can be used for the etchant. In step S1040, a part of the metal oxide film 135 is exposed.

In step S1050, a heat treatment is performed on the oxide semiconductor film 145. Hereinafter, the heat treatment performed in step S1050 is referred to as “OS annealing process.” In the OS annealing process, the oxide semiconductor film 145 is held at a predetermined reaching temperature for a predetermined time. The predetermined reaching temperature is higher than or equal to 250° C. and lower than or equal to 500° C., preferably higher than or equal to 300° C. and lower than or equal to 450° C., and more preferably higher than or equal to 350° C. and lower than or equal to 450° C. The holding time at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure (that is, the oxide semiconductor layer 140 including the Poly-OS) by the OS annealing process.

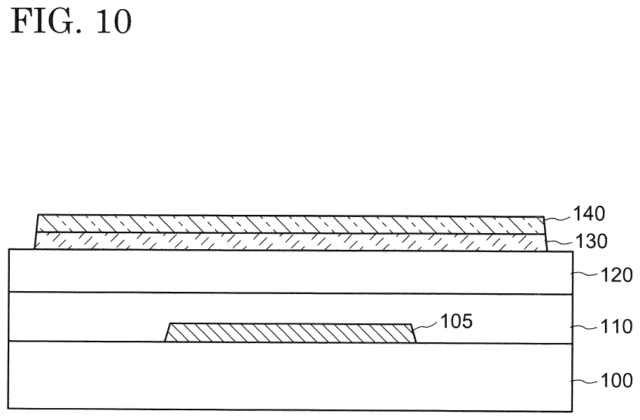

In step S1060, the metal oxide film 135 is patterned to form the metal oxide layer 130 (see FIG. 10). The metal oxide film 135 is etched using the oxide semiconductor layer 140 as a mask. When the patterned oxide semiconductor layer 140 is used as a mask, a photolithography process can be omitted. The metal oxide film 135 may be etched by wet etching or dry etching. For example, diluted hydrofluoric acid (DHF) is used for wet etching.

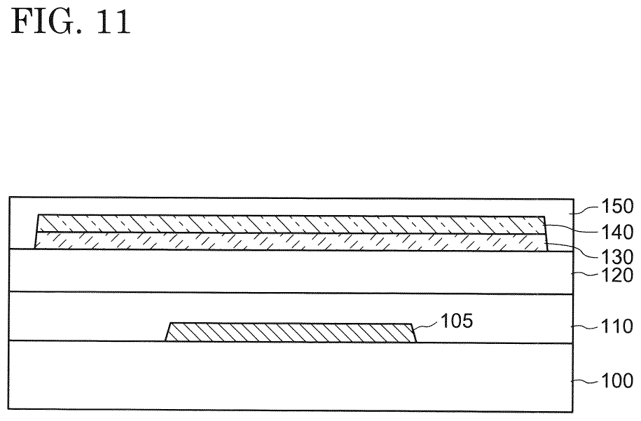

In step S1070, the gate insulating layer 150 is formed on the oxide semiconductor layer 140 (see FIG. 11). The gate insulating layer 150 is deposited using a CVD method. For example, silicon oxide is deposited for the gate insulating layer 150. In order to reduce defects in the gate insulating layer 150, the gate insulating layer 150 may be deposited at a deposition temperature higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm. After the gate insulating layer 150 is deposited, a treatment for introducing oxygen into a part of the gate insulating layer 150 may be performed. In step S1070, the edge surface of the metal oxide layer 130 is covered with the gate insulating layer 150.

In step S1080, a heat treatment is performed on the oxide semiconductor layer 140. Hereinafter, the heat treatment performed in step S1080 is referred to as “oxidation annealing process.” When the gate insulating layer 150 is formed on the oxide semiconductor layer 140, many oxygen vacancies are generated on the top surface and edge surfaces of the oxide semiconductor layer 140. Although a bottom surface of the oxide semiconductor layer 140 is in contact with the metal oxide layer 130, oxygen is supplied from the second insulating layer 120 and the gate insulating layer 150 to the oxide semiconductor layer 140, and oxygen vacancies are repaired when the oxidation annealing process is performed.

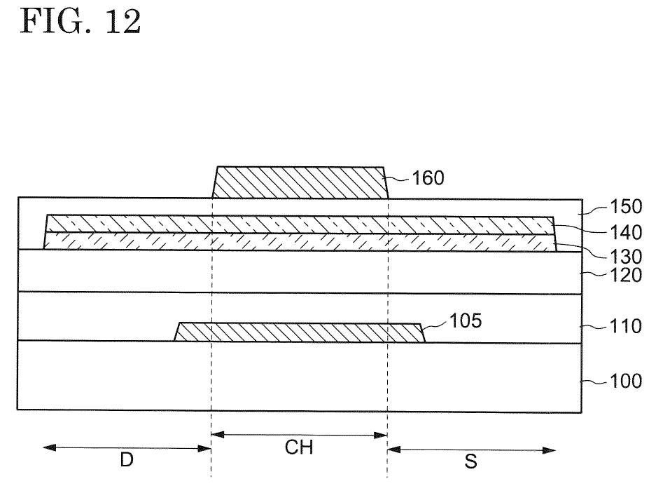

In step S1090, the gate electrode 160 having a predetermined pattern is formed on the gate insulating layer 150 (see FIG. 12). The gate electrode 160 is deposited by a sputtering method or an atomic layer deposition method, and patterning of the gate electrode 160 is performed using a photolithography method.

In step S1100, the source region S and the drain region D are formed in the oxide semiconductor layer 140 (see FIG. 12). The source region S and the drain region D are formed by ion implantation. Specifically, impurities are implanted into the oxide semiconductor layer 140 through the gate insulating layer 150 using the gate electrode 160 as a mask. For example, argon (Ar), phosphorus (P), boron (B), or the like is used as the implanted impurity. Oxygen deficiencies are generated by the ion implantation in the source region S and the drain region D that do not overlap the gate electrode 160, and hydrogen is trapped in the generated oxygen deficiencies. In this way, the resistance of the source region S and the drain region D is lowered. On the other hand, since no impurities are implanted in the channel region CH that overlaps the gate electrode 160, the resistance of the channel region CH is not lowered.

In addition, in the thin film transistor 10, since impurities are implanted into the oxide semiconductor layer 140 through the gate insulating layer 150, impurities such as argon (Ar), phosphorus (P), boron (B), or the like are included in the gate insulating layer 150.

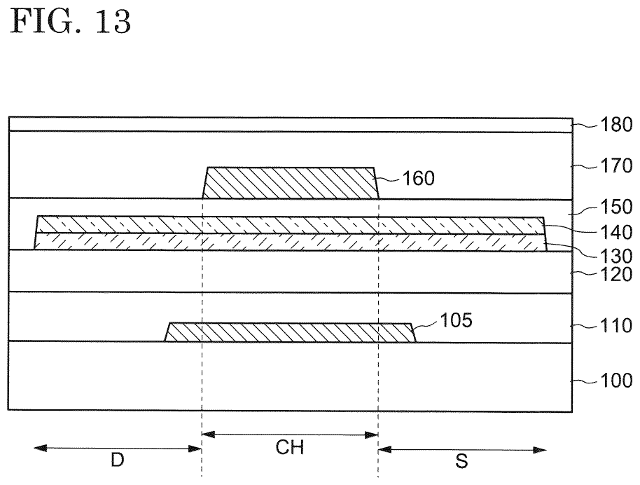

In step S1110, the third insulating layer 170 and the fourth insulating layer 180 are formed over the gate insulating layer 150 and the gate electrode 160 (see FIG. 13). The third insulating layer 170 and the fourth insulating layer 180 are deposited using a CVD method. For example, silicon oxide and silicon nitride are deposited for the third insulating layer 170 and the fourth insulating layer 180, respectively. The thickness of the third insulating layer 170 is greater than or equal to 50 nm and less than or equal to 500 nm. The thickness of the fourth insulating layer 180 is also greater than or equal to 50 nm and less than or equal to 500 nm.

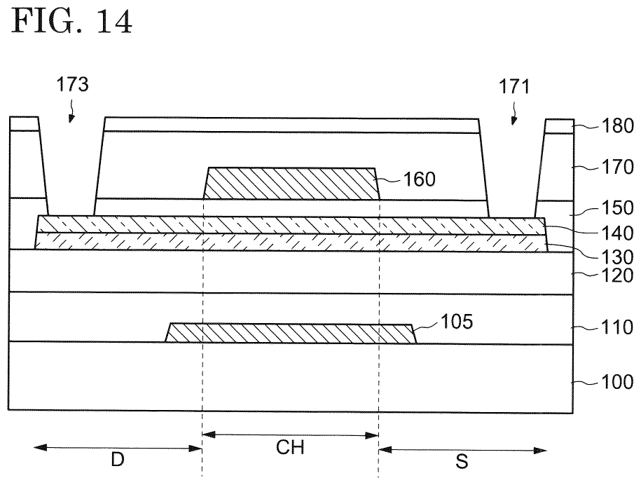

In step S1120, the opening portions 171 and 173 are formed in the gate insulating layer 150, the third insulating layer 170, and the fourth insulating layer 180 (see FIG. 14). The source region S and the drain region D of the oxide semiconductor layer 140 are exposed by the formation of the opening portions 171 and 173.

In step S1130, the source electrode 201 is formed on the fourth insulating layer 180 and inside the opening portion 171, and the drain electrode 203 is formed on the fourth insulating layer 180 and inside the opening portion 173. The source electrode 201 and the drain electrode 203 are formed as the same layer. Specifically, the source electrode 201 and the drain electrode 203 are formed by patterning one deposited conductive film. The thin film transistor 10 shown in FIG. 3 is manufactured through the above steps.

Although the method for manufacturing the thin film transistor 10 is described above, the method for manufacturing the thin film transistor 10 is not limited thereto.

In the thin film transistor 10 according to the present embodiment, the oxide semiconductor layer 140 includes the Poly-OS film having a novel crystal structure. Since the Poly-OS film includes many grain boundaries with high lattice matching and few defects, the grain boundary scattering is suppressed. As a result, the field effect mobility of the thin film transistor 10 is improved.

### Third Embodiment

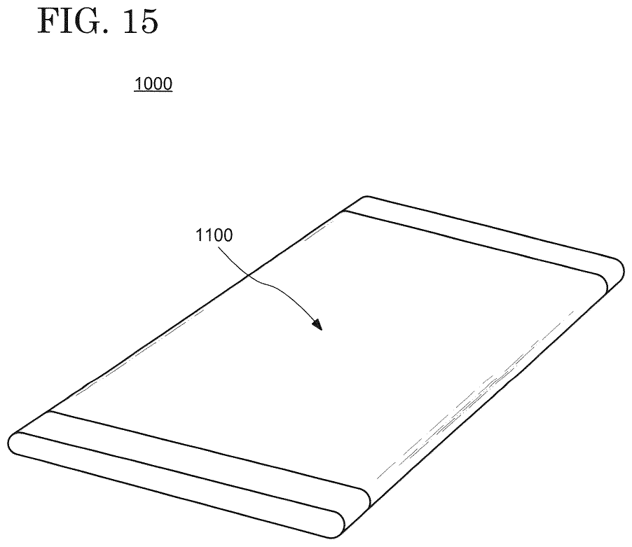

An electronic device according to an embodiment of the present embodiment is described with reference to FIG. 15.

FIG. 15 is a schematic diagram showing an electronic device 1000 according to an embodiment of the present embodiment. Specifically, FIG. 13 shows a smartphone, which is an example of the electronic device 1000. The electronic device 1000 includes a display device 1100 with curved sides. The display device 1100 includes a plurality of pixels for displaying an image. The plurality of pixels is controlled by a pixel circuit, a drive circuit, and the like. The pixel circuit and the drive circuit include the thin film transistor 10 described in the First Embodiment. Since the thin film transistor 10 has high field effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device, such as a watch, a tablet, a notebook computer, a car navigation system, or a television. Further, the thin film transistor 10 described in the Second Embodiment can be applied to any electronic device, regardless of whether or not the electronic device has a display device.

### Examples

The Poly-OS film is described in more detail based on the fabricated samples.

### [1. Crystal Orientation Analysis]

### [1-1. Fabrication of Example Samples]

As Example Samples, oxide semiconductor films (Poly-OS films) in contact with an aluminum oxide film were fabricated on glass substrates on which an aluminum oxide film is formed, using the sputtering process and the OS annealing process described in the Second Embodiment. A sputtering target in which the atomic ratio of indium to all metal elements contained in the sintered body was 70% was used in the sputtering process. The oxide semiconductor film was held for 60 minutes at the reaching temperature of 450° C. in the OS annealing process. In all of the Example Samples, the chemical composition of the oxide semiconductor film after the OS annealing process was similar to that of the sputtering target.

Example Samples 1-1 to 1-4 were fabricated under different fabrication conditions. The fabrication conditions for each Example Sample are shown in Table 1.

TABLE 1

| | | | oxygen |
|---|---|---|---|
| Example | oxide | film | partial |
| Sample | aluminum | thickness | pressure |
| 1-1 | Yes | 15 nm | 1% |
| 1-2 | Yes | 15 nm | 5% |
| 1-3 | Yes | 15 nm | 10% |
| 1-4 | Yes | 30 nm | 10% |

### [1-2. Crystal Structure Analysis by XRD Method]

The crystal structure of the oxide semiconductor film of each of the fabricated Example Samples was analyzed by an XRD method. All of the oxide semiconductor films had crystallinity and had a bixbyite crystal structure.

### [1-3. Crystal Orientation Analysis by EBSD Method]

The crystal orientation of the oxide semiconductor film of each of the fabricated Example Samples was analyzed by an EBSD method. The measurement conditions of the EBSD method are shown in Table 2. The crystal orientation was analyzed using an OIM-Analysis (ver. 7.1) manufactured by TSL Solutions Co., Ltd. The determination of the crystal orientation of the crystal structure used the crystal structure file of the bixbyite structure 14388 of ICSD (Inorganic Crystal Structure Database: Association for Chemical Information). As a result of the measurement and analysis, when the CI value was greater than or equal to 0.6, it was determined that the obtained pattern was sufficiently clear and the crystal orientation was specified as the bixbyite structure.

TABLE 2

| | Thermal field emission scanning electron | |
|---|---|---|
| | microscope (TFE-SEM) manufactured by JEOL Ltd. | |
| Device | JSM-6500F | |
| Acceleration | 10 | kV |
| voltage | | |
| Irradiation | 15 | nA |
| current | | |
| Sample tilt | 70 | degrees |
| Measurement | 20 μm × 20 μm | |
| region | | |
| Measurement | 80 | nm/step |
| interval | | |

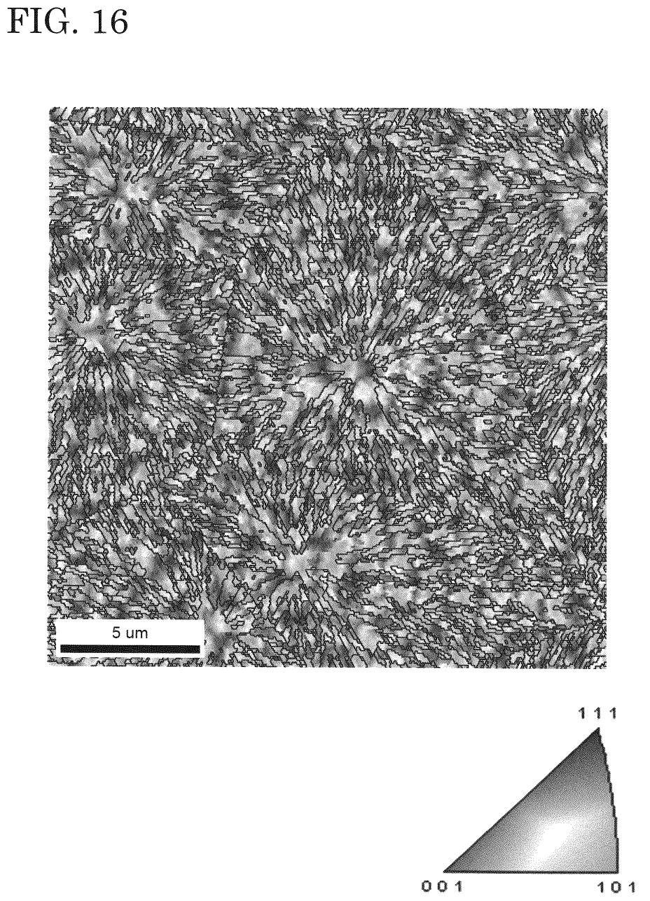

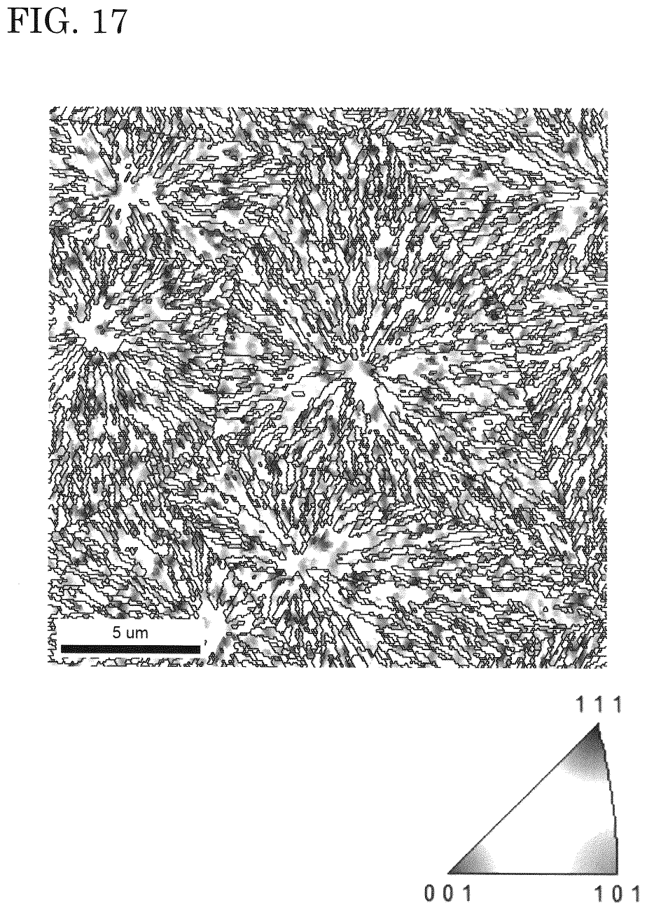

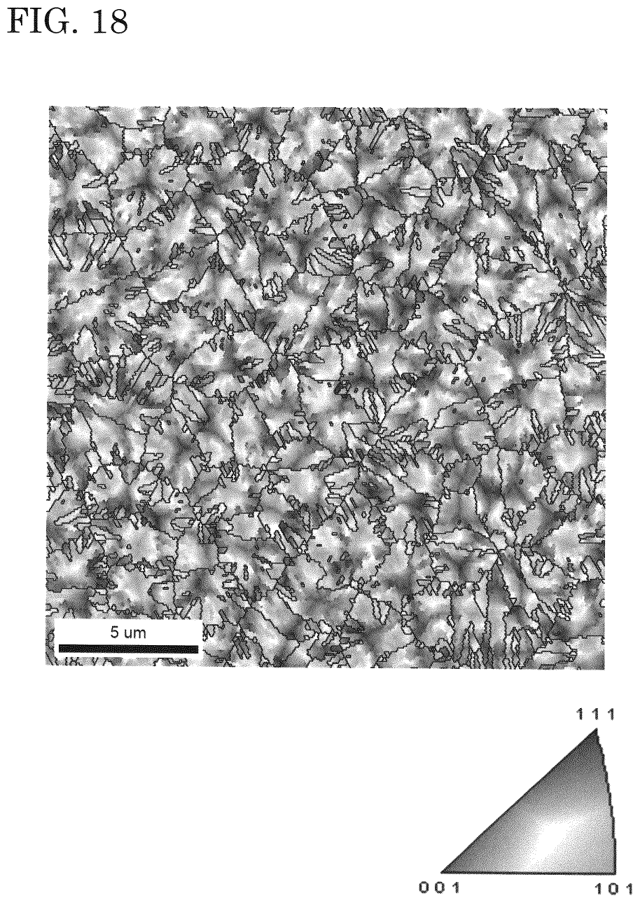

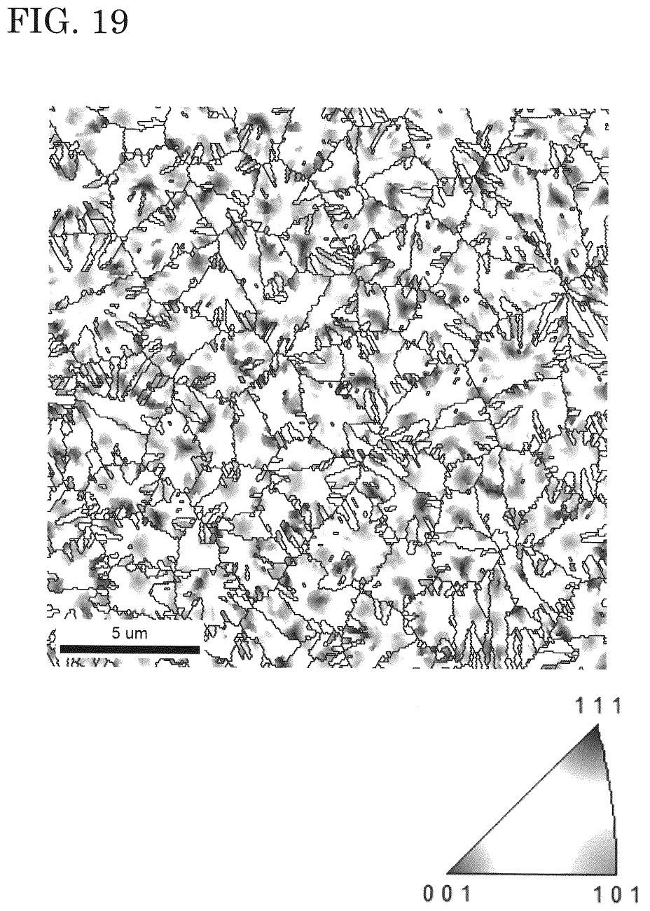

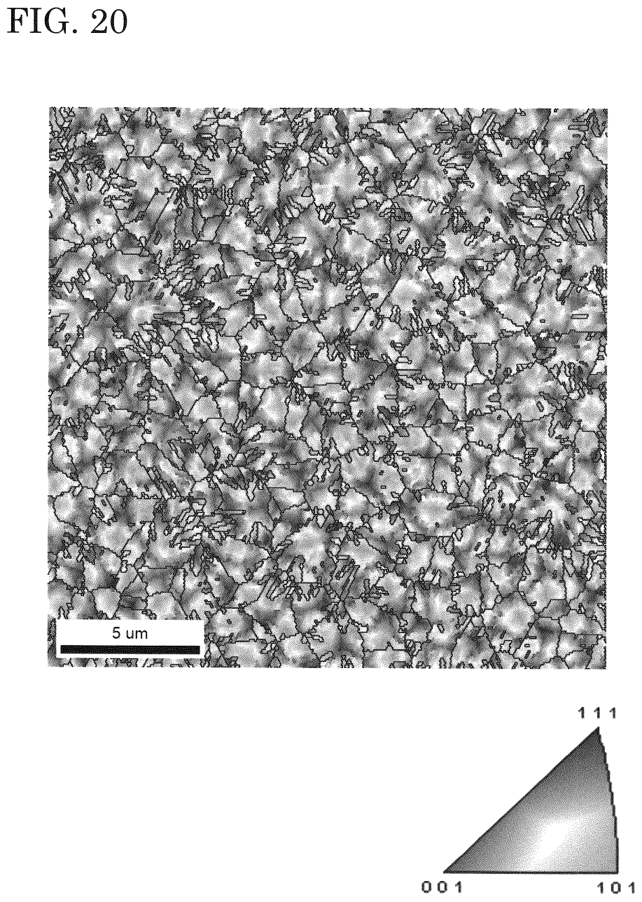

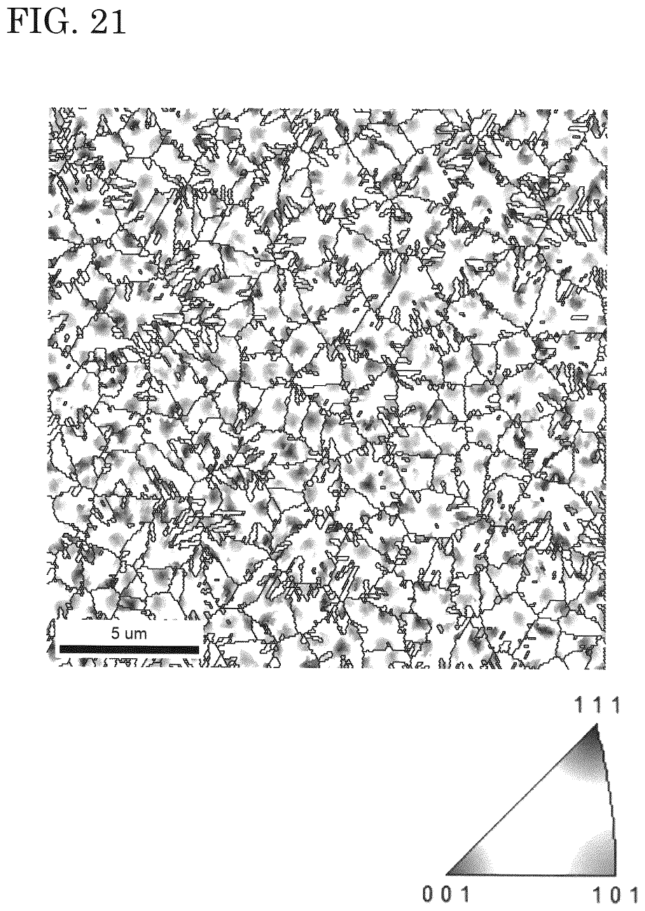

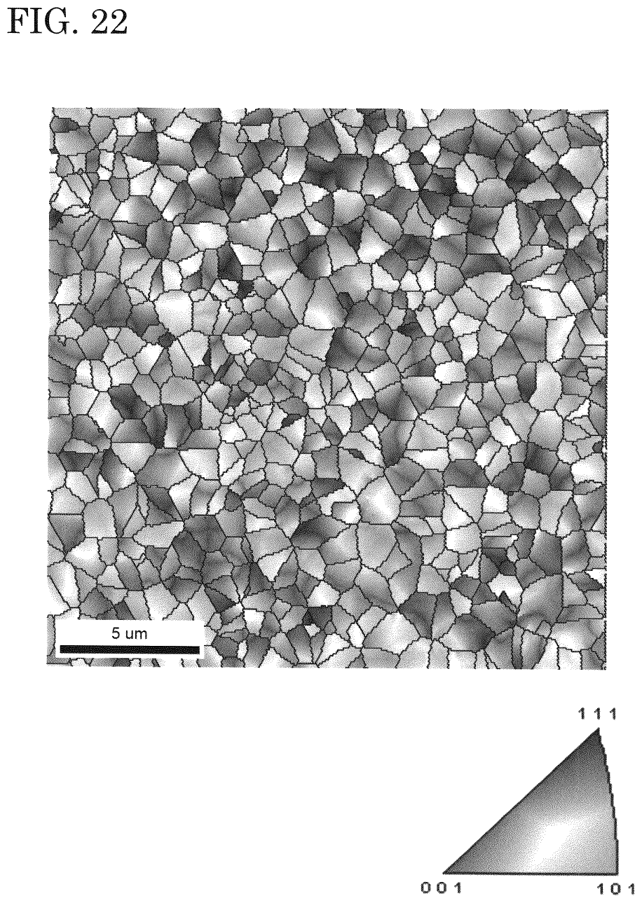

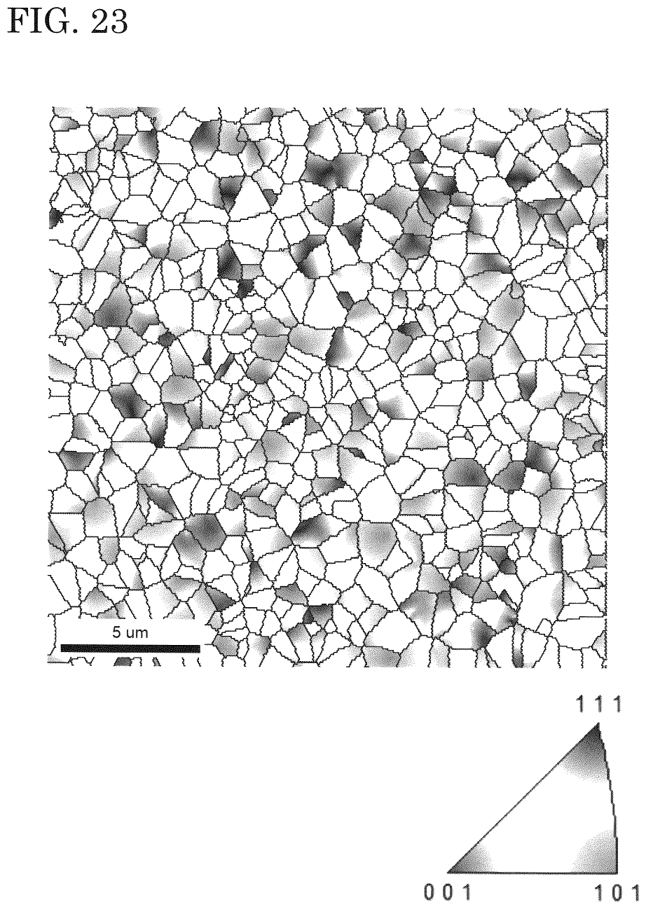

FIGS. 16 and 17 show IPF maps in the normal direction (ND) with respect to the surface of the oxide semiconductor film of Example Sample 1-1. FIGS. 18 and 19 show IPF maps in the ND direction of Example Sample 1-2. FIGS. 20 and 21 show IPF maps in the ND direction of Example Sample 1-3. FIGS. 22 and 23 show IPF maps in the ND direction of Example Sample 1-4. In FIGS. 16 to 23, the crystal orientation at each measurement point in the ND direction is defined by an index. Specifically, the crystal orientation at each measurement point in the ND direction is defined based on the crystal orientation <001>, the crystal orientation <101>, and the crystal orientation <111>. Further, when a crystal orientation difference between two adjacent measurement points exceeds 5 degrees, it is defined that a grain boundary exists between them and the grain boundary is shown by a black line. In FIGS. 17, 19, 21, and 23, regions in which the crystal orientation <001>, the crystal orientation <101>, and the crystal orientation <111> are oriented within 15 degrees with respect to the ND are extracted and defined. In other words, FIGS. 17, 19, 21, and 23 are IPF maps in which regions in FIGS. 16, 18, 20, and 22, respectively, in which the crystal orientation difference between the crystal orientation <001>, the crystal orientation <101>, or the crystal orientation <111> with respect to the ND exceeds 15 degrees are excluded.

As shown in FIGS. 16 to 23, the oxide semiconductor films of Example Samples 1-1 to 1-4 all include the plurality of crystal grains defined by grain boundaries. The average crystal grain sizes of the oxide semiconductor films of Example Samples 1-1 to 1-4 were 0.9 μm, 1.7 μm, 1.3 μm, and 1.0 μm, respectively, which were larger than the thicknesses of the oxide semiconductor films. In FIGS. 16, 18, 20, and 22, the plurality of crystal orientations can be confirmed in the crystal grain. Therefore, the oxide semiconductor films of Example Samples 1-1 to 1-4 are all Poly-OS films in which the crystal orientation changes in one crystal grain. Further, in the oxide semiconductor films of Example Samples 1-1 to 1-4, regions defined by the <001> crystal orientation, the <101> crystal orientation, and the <111> crystal orientation can be confirmed in one crystal grain. That is, at least one crystal grain in each of the oxide semiconductor films of Example Samples 1-1 to 1-4 includes a crystal orientation <001> region, a crystal orientation <101> region, and a crystal orientation <111> region, and the crystal orientation changes significantly in the crystal grain.

Based on the IPF maps shown in FIGS. 17, 19, 21, and 23, the occupancy ratios of the crystal orientation <101> region, the crystal orientation <101> region, and the crystal orientation <111> region were calculated (the measured region is set to 100%). The occupancy ratios for Example Samples 1-1 to 1-4 are shown in Table 3.

TABLE 3

| | occupancy ratio | occupancy ratio | occupancy ratio |
|---|---|---|---|
| | of crystal | of crystal | of crystal |
| | orientation | orientation | orientation |
| Example | <001> region | <101> region | <111> region |
| Sample | (%) | (%) | (%) |
| 1-1 | 5.2 | 24.6 | 19.6 |
| 1-2 | 7.2 | 23.9 | 16.7 |
| 1-3 | 8.9 | 21.9 | 15.5 |
| 1-4 | 6.4 | 21.2 | 18.4 |

In all of Example Samples 1-1 to 1-4, the occupancy ratio of the crystal orientation <101> region is greater than or equal to 20%. In Example Sample 1-1 to Example Sample 1-3, which have the same thickness of the oxide semiconductor film, the occupancy ratio of the crystal orientation <101> region increases as the oxygen partial pressure in the film deposition of the oxide semiconductor film decreases. Further, in all of Example Samples 1-1 to 1-4, the occupancy ratio of the crystal orientation <111> region is greater than or equal to 15%. In Example Samples 1-1 to 1-3, which have the same thickness of the oxide semiconductor film, the occupancy ratio of the crystal orientation <111> region increases as the oxygen partial pressure in the film deposition of the oxide semiconductor film decreases. On the other hand, in all of Example Samples 1-1 to 1-4, the occupancy ratio of the crystal orientation <001> region is less than 10%. In Example Samples 1-1 to 1-3, which have the same thickness of the oxide semiconductor film, the occupancy ratio of the crystal orientation <001> region decreases as the oxygen partial pressure in the film deposition of the oxide semiconductor film decreases.

In other words, the occupancy ratio of the crystal orientation <001> region is smaller than the occupancy ratio of the crystal orientation <101> region and the occupancy ratio of the crystal orientation <111> region. The occupancy ratio of the crystal orientation <101> region is at least twice as high as the occupancy ratio of the crystal orientation <001> region. Further, the occupancy ratio of the crystal orientation <111> region is at least 1.5 times as high as the occupancy ratio of the crystal orientation <001> region. Furthermore, the occupancy ratio of the crystal orientation <101> region is larger than the occupancy ratio of the crystal orientation <111> region.

The total occupancy ratio of the crystal orientation <101> region and the crystal orientation <111> region is greater than or equal to 40%. In this way, in the Poly-OS film, the <101> crystal orientation and the <111> crystal orientation are preferentially oriented in the film thickness direction.

Next, an analysis based on the crystal orientation difference between two adjacent measurement points is described. In addition, hereinafter, the crystal orientation difference between two measurement points may be simply referred to as “orientation difference.”

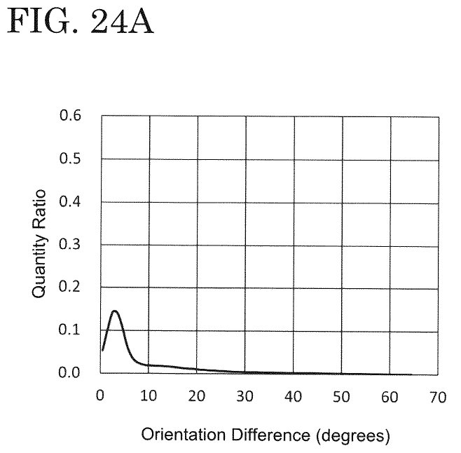

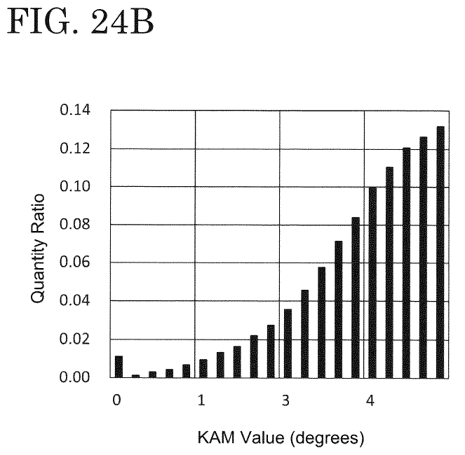

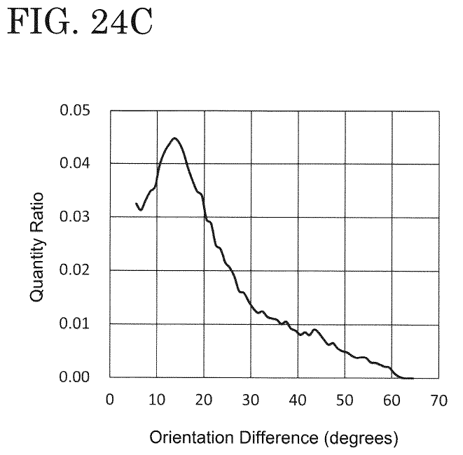

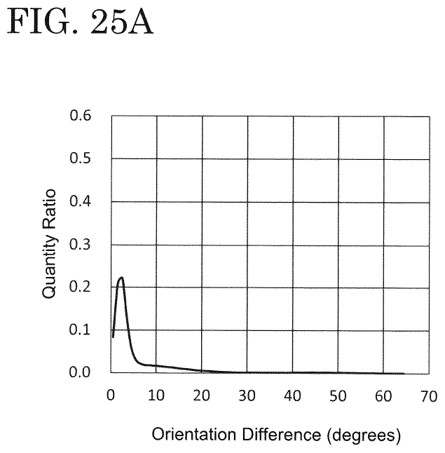

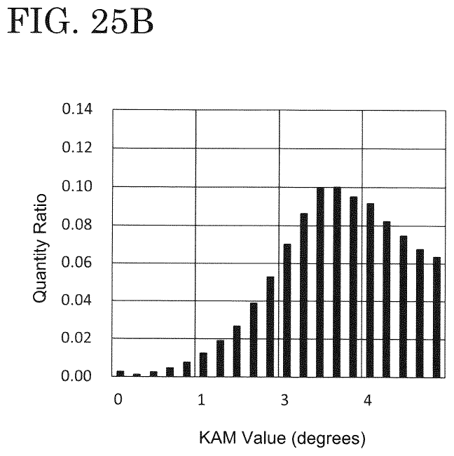

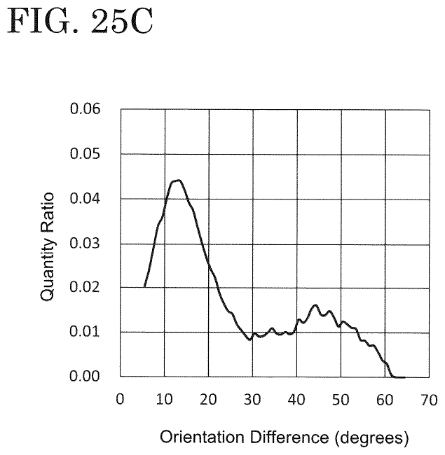

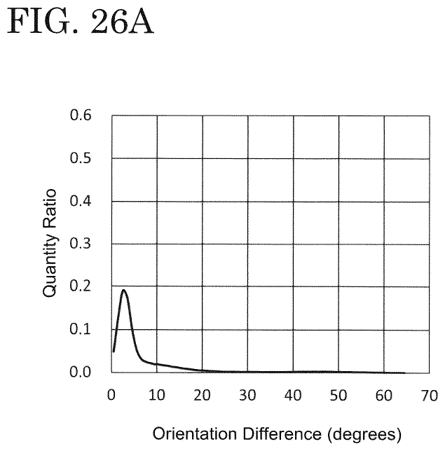

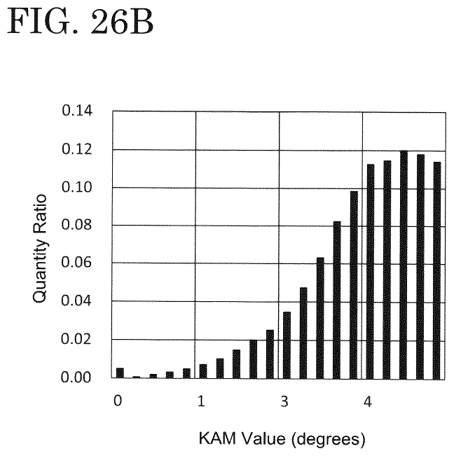

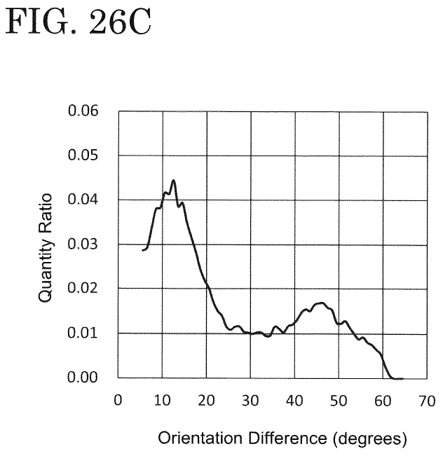

FIGS. 24A to 27C show graphs relating to the distribution of crystal orientation difference of the oxide semiconductor films of Example Samples 1-1 to 1-4. FIGS. 24A, 25A, 26A, and 27A show graphs representing distribution diagrams of all adjacent point orientation changes in Example Samples 1-1 to 1-4, respectively. FIGS. 24B, 25B, 26B, and 27B show graphs representing distribution diagrams of KAM values in Example Samples 1-1 to 1-4, respectively. FIGS. 24C, 25C, 26C, and 27C show graphs representing distribution diagrams of grain boundary orientation changes in Example Samples 1-1 to 1-4, respectively. The distribution diagrams of all adjacent point orientation changes show all crystal orientation differences between two adjacent measurement points.

According to FIGS. 24C, 250, 26C, and 27C, peaks can be seen at angles of approximately 10 degrees and 45 degrees in the distribution diagram of the grain boundary orientation change. When the thickness of the oxide semiconductor film decreases or the oxygen partial pressure in the film deposition of the oxide semiconductor film decreases, the peak at approximately 10 degrees becomes larger than the peak at approximately 45 degrees.

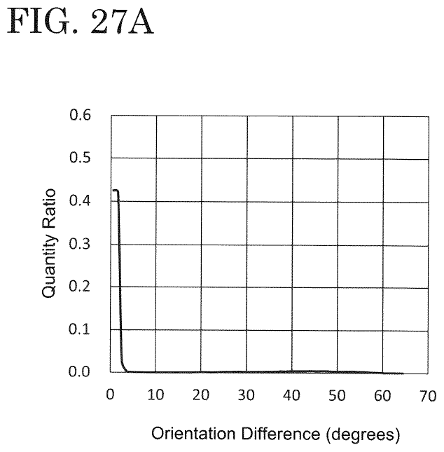

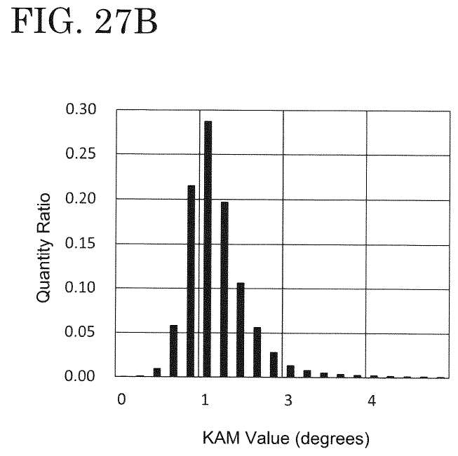

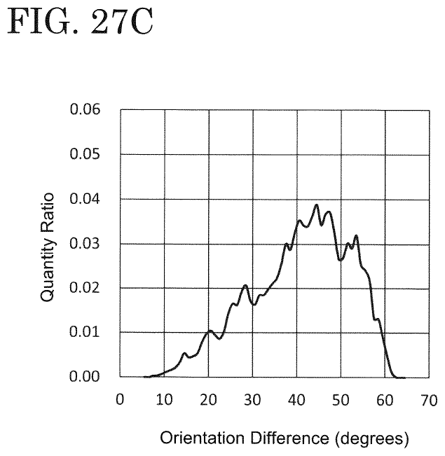

According to FIGS. 24B, 25B, and 26B, the KAM value greater than or equal to 3 degrees is clearly observed in the distribution diagram of the KAM value. Further, according to FIGS. 24B, 25B, and 26B, the KAM value around 5 degrees is also observed. On the other hand, the KAM value greater than or equal to 3 degrees is hardly observed in the distribution diagram of the KAM value of FIG. 27B.

Here, a ratio of the average value of the grain boundary orientation changes to the average KAM value is defined as a grain boundary parameter PGB ((the grain boundary parameter PGB)=(the average value of the grain boundary orientation changes)/(the average KAM value)). The grain boundary parameter PGB is a parameter that represents the ratio of the amount of change in the crystal orientation at the grain boundary to the amount of change in the crystal orientation in the crystal grain. When the grain boundary parameter PGB is large, it means that the local change in the crystal orientation in the crystal grain is small, and the crystal orientation difference between two adjacent measurement points across the grain boundary is large. In contrast, the smaller the grain boundary parameter P_{GB} is and the closer it is to 1, the larger the local change in the crystal orientation in the crystal grain, and the higher the lattice matching between the two adjacent measurement points across the grain boundary. In other words, the smaller the grain boundary parameter P_{GB} is and the closer it is to 1, the higher the lattice matching of the oxide semiconductor film and the more grain boundaries with fewer defects are included.

Table 4 shows the average KAM value, the average value of the grain boundary orientation changes, and the grain boundary parameter P_{GB} for each of the oxide semiconductor films of Example Samples 1-1 to 1-4.

TABLE 4

| | | average value of | grain boundary |
|---|---|---|---|
| Example | average | grain boundary | parameter |
| Sample | KAM value | orientation changes | P_{GB} |
| 1-1 | 3.74 degrees | 21.3 degrees | 5.69 |
| 1-2 | 3.39 degrees | 24.8 degrees | 7.31 |
| 1-3 | 3.77 degrees | 25.3 degrees | 6.71 |
| 1-4 | 1.53 degrees | 40.8 degrees | 26.7 |

As shown in Table 4, the average KAM values is greater than or equal to 1.0 degree in each of the oxide semiconductor films of Example Samples 1-1 to 1-4. In particular, the average KAM value is greater than or equal to 3.0 degrees in each of the oxide semiconductor films of Example Samples 1-1 to 1-3, in which the thickness of the oxide semiconductor film is less than 30 nm. Further, the average value of the grain boundary orientation changes is less than or equal to 50 degrees in each of the oxide semiconductor films of Example Samples 1-1 to 1-4. Furthermore, the grain boundary parameter P_{GB} is less than or equal to 30 in each of the oxide semiconductor films of Example Samples 1-1 to 1-4. In particular, the grain boundary parameter P_{GB} is less than or equal to 10 in each of Example Samples 1-1 to 1-3, in which the thickness of the oxide semiconductor film is less than 30 nm. As described above, the smaller the grain boundary parameter P_{GB} is and the closer it is to 1, the higher the oxide semiconductor film has the lattice matching and the more grain boundaries with fewer defects the oxide semiconductor film contains. In the Poly-OS film, the crystal orientations in two adjacent crystal grains change so that the lattice matching at the grain boundary is improved. As a result, the lattice matching at the grain boundary is improved and the grain boundary has fewer defects.

### [2. Electrical Characteristics]

Thin film transistors including oxide semiconductor films of Example Samples 1-1 to 1-4 were fabricated using the manufacturing method described in the Second Embodiment, and the electrical characteristics of the fabricated thin film transistors were measured. Table 5 shows the field effect mobility (field effect mobility in the saturation region) calculated from the electrical characteristics.

TABLE 5

| Example | field effect mobility |
|---|---|
| Sample | (cm²/Vs) |
| 1-1 | 48.3 |
| 1-2 | 46.2 |
| 1-3 | 45.0 |
| 1-4 | 38.9 |

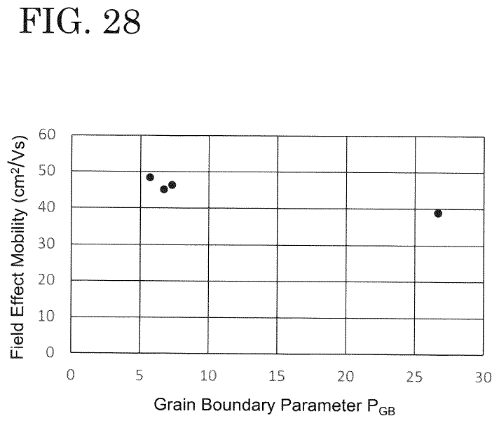

As shown in Table 5, the field effect mobility greater than 35 cm²/Vs is obtained in all of the thin film transistors of Example Samples 1-1 to 1-4. In particular, Example Samples 1-1 to 1-3, in which the thickness of the oxide semiconductor film is less than 30 nm, had the field effect mobility greater than or equal to 40 cm²/Vs. FIG. 28 is a graph showing a correlation between the field effect mobility and the grain boundary parameter P_{GB} in Example Samples 1-1 to 1-4. When the grain boundary parameter P_{GB} is less than or equal to 10, the field effect mobility greater than or equal to 40 cm²/Vs is obtained. Further, when the grain boundary parameter P_{GB} decreases, the field effect mobility tends to increase. As can be seen from these results, the use of a Poly-OS film as the channel of a thin film transistor improved the field effect mobility.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A thin film transistor, comprising:
an oxide semiconductor layer having a polycrystalline structure;
a metal oxide layer in contact with the oxide semiconductor layer;
a gate electrode provided so as to overlap the oxide semiconductor layer; and
a gate insulating layer provided between the oxide semiconductor layer and the gate electrode,
wherein the oxide semiconductor layer comprises a plurality of crystal grains, each of which has at least one of a crystal orientation <101>, a crystal orientation <111>, and a crystal orientation <001> that are measured by an electron backscatter diffraction method,
wherein the oxide semiconductor layer comprises a first region in which the crystal orientation <101> is oriented within 15 degrees with respect to a normal direction of a surface of the semiconductor layer, and
wherein an occupancy ratio of the first region is greater than or equal to 20%.

2. The thin film transistor according to claim 1, wherein an average value of KAM (Kernel Average Misorientation) values calculated by the electron backscatter diffraction method is greater than or equal to 1.0 degree.

3. The thin film transistor according to claim 1,
wherein the oxide semiconductor layer comprises a second region in which the crystal orientation <111> is oriented within 15 degrees with respect to the normal direction of the surface of the semiconductor layer, and
wherein an occupancy ratio of the second region is greater than or equal to 15%.

4. The thin film transistor according to claim 1, wherein a total occupancy ratio of the first region and the second region is greater than or equal to 40%.

5. The thin film transistor according to claim 1,
wherein the oxide semiconductor layer comprises a third region in which the crystal orientation <001> is oriented within 15 degrees with respect to the normal direction of the surface of the semiconductor layer, and
wherein an occupancy ratio of the third region is less than 10%.

6. The thin film transistor according to claim 1, wherein a band gap of a metal oxide contained in the metal oxide layer is greater than or equal to 4 eV.

7. The thin film transistor according to claim 1, wherein the metal oxide layer contains one or more metal elements selected from aluminum, magnesium, calcium, scandium, gallium, germanium, strontium, nickel, tantalum, yttrium, zirconium, barium, hafnium, cobalt, and lanthanoid elements.

8. A thin film transistor, comprising:
an oxide semiconductor layer having a polycrystalline structure;
a metal oxide layer in contact with the oxide semiconductor layer;
a gate electrode provided so as to overlap the oxide semiconductor layer; and
a gate insulating layer provided between the oxide semiconductor layer and the gate electrode,
wherein the oxide semiconductor layer comprises a plurality of crystal grains, each of which has at least one of a crystal orientation <101>, a crystal orientation <111>, and a crystal orientation <001> that are measured by an electron backscatter diffraction method,
wherein in the oxide semiconductor layer,
a region in which the crystal orientation <101> is oriented within 15 degrees with respect to a normal direction of a surface of the semiconductor layer is defined as a first region,
a region in which the crystal orientation <111> is oriented within 15 degrees with respect to the normal direction of the surface of the semiconductor layer is defined as a second region, and
a region in which the crystal orientation <001> is oriented within 15 degrees with respect to the normal direction of the surface of the semiconductor layer is defined as a third region, and
wherein an occupancy ratio of the third region is less than an occupancy ratio of the first region and an occupancy ratio of the second region.

9. The thin film transistor according to claim 8, wherein an average value of KAM (Kernel Average Misorientation) values calculated by the electron backscatter diffraction method is greater than or equal to 1.0 degree.

10. The thin film transistor according to claim 8, wherein the occupancy ratio of the first region is greater than the occupancy ratio of the second region.

11. The thin film transistor according to claim 8, wherein the occupancy ratio of the first region is greater than or equal to 2.0 times the occupancy ratio of the third region.

12. The thin film transistor according to claim 8, wherein the occupancy ratio of the first region is greater than or equal to 1.5 times the occupancy ratio of the third region.

13. The thin film transistor according to claim 8, wherein an average value of grain boundary orientation changes calculated by the electron backscatter diffraction method is less than or equal to 50 degrees.

14. The thin film transistor according to claim 8, wherein a thickness of the oxide semiconductor layer is less than 30 nm.

15. The thin film transistor according to claim 8,
wherein the oxide semiconductor layer comprises:
indium, and
at least one metal element other than the indium, and
wherein an atomic ratio of the indium to the indium and the at least one metal element is greater than or equal to 50%.

16. The thin film transistor according to claim 8, wherein a band gap of a metal oxide contained in the metal oxide layer is greater than or equal to 4 eV.

17. The thin film transistor according to claim 16, wherein the metal oxide layer contains one or more metal elements selected from aluminum, magnesium, calcium, scandium, gallium, germanium, strontium, nickel, tantalum, yttrium, zirconium, barium, hafnium, cobalt, and lanthanoid elements.

18. The thin film transistor according to claim 8, wherein a crystal structure of the oxide semiconductor layer is a bixbyite structure.

19. An electronic device comprising the thin film transistor according to claim 1.
